(19) United States
(12) Patent Application Publication
(10) Pub. No.: US 2015/0364676 A1
(43) Pub. Date: Dec. 17, 2015

(54) THREE-TERMINAL SPIN TRANSISTOR MAGNETIC RANDOM ACCESS MEMORY AND THE METHOD TO MAKE THE SAME

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/301,335

(22) Filed: Jun. 11, 2014

(51) Int. Cl. H01L 43/08; H01L 43/10; H01L 43/12; H01L 43/02

(52) U.S. Cl. CPC H01L 43/08; H01L 43/02; H01L 43/10; H01L 43/12

(57) ABSTRACT

This invention is about a three-terminal spin transistor magnetic random access memory and the method to make it with a narrow foot print. The first terminal, a bit line, is connected to the top magnetic reference layer, and the second terminal is located at the middle memory layer which is connected to the underneath CMOS control circuit through VIA and the third one, a digital line, is a voltage gate with a narrow point underneath the memory layer across an insulating layer which is used to reduce the write current when it is turned on. The fabrication includes formation of a large VIA base, formation of digital line, formation of memory cell & VIA connection and formation of the top bit line. Dual photolithography patterning and hard mask etch are used to form the digital line pillar and small memory pillar. Oxygen plasma ion implantation is used to define an insulating region underneath the memory cell and metallic ion implantation is used to convert a buried dielectric VIA base outside the center memory pillar into an electric conductive path between middle memory cell and underneath CMOS device.

### RELATED APPLICATIONS

This application claims the priority benefit of U.S. Provisional Application No. 61/834,562 filed on Jun. 13, 2013, which is incorporated herein by reference.

### BACKGROUND OF THE INVENTION

1. Field of the Invention

This invention relates generally to a three terminal magnetic-random-access memory (MRAM) cell, more particularly to methods of fabricating three terminal MRAM memory elements having ultra-small dimensions.

2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can also cope with high-speed reading and writing. A ferromagnetic tunnel junction has a three-layer stack structure formed by stacking a recording layer having a changeable magnetization direction, an insulating tunnel barrier layer, and a fixed layer that is located on the opposite side from the recording layer and maintains a predetermined magnetization direction. Corresponding to the parallel and anti-parallel magnetic states between the recording layer magnetization and the reference layer magnetization, the magnetic memory element has low and high electrical resistance states, respectively. Accordingly, a detection of the resistance allows a magnetoresistive element to provide information stored in the magnetic memory device.

Typically, MRAM devices are classified by different write methods. A traditional MRAM is a magnetic field-switched MRAM utilizing electric line currents to generate magnetic fields and switch the magnetization direction of the recording layer in a magnetoresistive element at their cross-point location during the programming write. A spin-transfer torque (or STT)-MRAM has a different write method utilizing electrons' spin momentum transfer. Specifically, the angular momentum of the spin-polarized electrons is transmitted to the electrons in the magnetic material serving as the magnetic recording layer. According to this method, the magnetization direction of a recording layer is reversed by applying a spin-polarized current to the magnetoresistive element. As the volume of the magnetic layer forming the recording layer is smaller, the injected spin-polarized current to write or switch can be also smaller.

Besides a write current, the stability of the magnetic orientation in a MRAM cell as another critical parameter has to be kept high enough for a good data retention, and is typically characterized by the so-called thermal factor which is proportional to the energy barrier as well as the volume of the recording layer cell size.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus unintentionally reversing the direction of magnetization of the recording layer in MTJ.

Above issues or problems are all associated with the traditional two-terminal MRAM configuration. Thus, it is desirable to provide robust STT-MRAM structures and methods that realize highly-accurate reading, highly-reliable recording and low power consumption while suppressing destruction and reduction of life of MTJ memory device due to recording in a nonvolatile memory that performs recording resistance changes, and maintaining a high thermal factor for a good data retention.

It is known that perpendicular magnet (PM) spin transfer torque magnetic random access memory pSTT-MRAM) is an ideal memory for future semiconducting device. Current STT-MRAM is a two-terminal device with magnetic memory layer and reference layer separated by a thin MgO dielectric layer to form a so-called magnetic tunneling junction (MTJ). The shortcomings of such two-terminal pSTT-MRAM are its large critical write current and narrow current separation between read and write process. It has been recently reported that by applying a bias voltage across the MTJ junction with a right polarization could reduce the Hc of the magnetic layer adjacent to the MgO layer. A so-called voltage-controlled pSTT-MRAM has been proposed [W.-G. Wang et al., Natural Materials, Vol. 11, 64, 2012].

### BRIEF SUMMARY OF THE PRESENT INVENTION

The present invention comprises methods of making a low power spin-transfer-torque MRAM comprising three terminals: an upper electrode connected to a bit line, a middle electrode connected to a select transistor and a digital line as a bottom electrode wherein an MTJ stack is sandwiched between an upper electrode and a middle electrode, a dielectric functional layer is sandwiched between a middle electrode and a digital line of each MRAM memory cell.

The memory cell further includes a circuitry coupled to the bit line positioned adjacent to selected ones of the plurality of magnetoresistive memory elements to supply a reading current or bi-directional spin polarized current to the MTJ stack, and coupled to the digital line configured to generate an electric field on the functional layer and accordingly to decrease the switching energy barrier of the recording layer. Thus magnetization of a recording layer can be readily switched or reversed to the direction in accordance with a direction of a current across the MTJ stack by applying a low spin transfer current.

The fabrication method of the MRAM cell includes formation of bottom electrode, formation of middle electric connecting layer, formation of magnetic memory cell and formation of top electrode and bit line, by repeated film deposition, photolithography patterning, etching, dielectric refilling and chemical mechanic lapping, in which metallic ion implantation is used to convert the isolated middle layers into electrically conducting layer to allow the current flow between middle magnetic recording layer and bottom electrode.

The exemplary embodiment will be described hereinafter with reference to the companying drawings. The drawings are schematic or conceptual, and the relationships between the thickness and width of portions, the proportional coefficients of sizes among portions, etc., are not necessarily the same as the actual values thereof.

### BRIEF DESCRIPTION OF THE DRAWINGS

FIG. 1 Schematics of three-terminal spin transistor magnetic random access memory.

FIG. 2 Process flow to make three-terminal spin transistor magnetic random access memory.

FIG. 3 Substrate with CMOS built-in (not shown) and VIA to connect to the top magnetic memory cell to be built.

FIG. 4 VIA base film stack is deposited.

FIG. 5 VIA base is formed by patterning, etch and dielectric refill and CMP.

FIG. 6 Digital line film stack is deposited with an insulating layer (310) separating it from the bottom VIA base.

FIG. 7 Digital line top connecting pillar is formed by patterning and reactive ion etch.

FIG. 8 Digital base line is formed by patterning and reactive ion etch.

FIG. 9 The etched portion of digital line film stack is dielectric refilled and CMP to flatten the surface.

FIG. 10 VIA base is patterned and RIE to open a connection ring.

FIG. 11(A) Top surface and the open space of VIA base connection ring is filled by a conducting metallic layer.

FIG. 11(B) Top surface is deposited an ion implantation mask layer.

FIG. 12(A) Photolithography patterning and etching are used to define an ion implantation mask. Oxygen plasma ion implantation is used to create electrically isolation region.

FIG. 12(B) Top ion implantation mask layer is removed by RIE to form a flat surface.

FIG. 13 TMR memory film stack is deposited.

FIG. 14 Memory pillar is formed by patterning, etch and ALD refill.

FIG. 15 Metal ion implantation is used add metal ions into the un-etched memory film stack including the buried insulating layer, (a) cross section view and (b) top view.

FIG. 16 Middle electric connection base is formed by patterning, etch, dielectric refill and CMP.

FIG. 17 Top bit line is formed by film stack deposition, patterning, etch, dielectric refill and CMP.

### DETAILED DESCRIPTION OF THE INVENTION

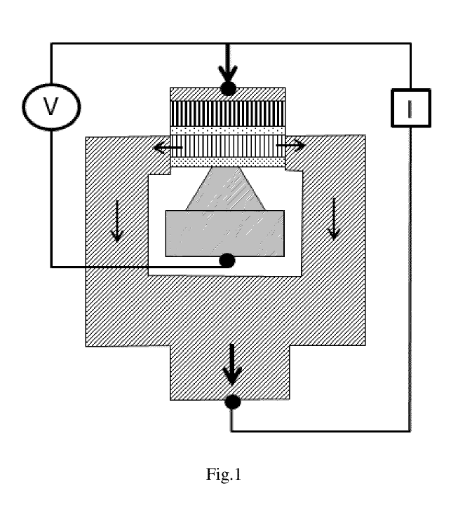

The three-terminal spin transistor magnetic random access memory (FIG. 1) contains a digital line at the bottom, a bit line on the top, and a magnetic memory cell in the middle. The middle memory cell has a bottom insulating layer (ILD), a magnetic memory layer, a dielectric MgO tunneling layer, a top reference layer, a cap layer and hard mask. The top reference layer has perpendicular magnetization to the plane, and the polarization of the middle memory layer can be either perpendicular to the plane or in the plane depending on the voltage applied between the top bit line and bottom digital line. Both read and write current flow through the top reference layer, middle memory film stack and VIA to/from the underneath CMOS control circuit (not shown). The digital line has a small contact area with the insulating layer below the memory cell which helps to reduce writing current when a voltage pulse is applied.

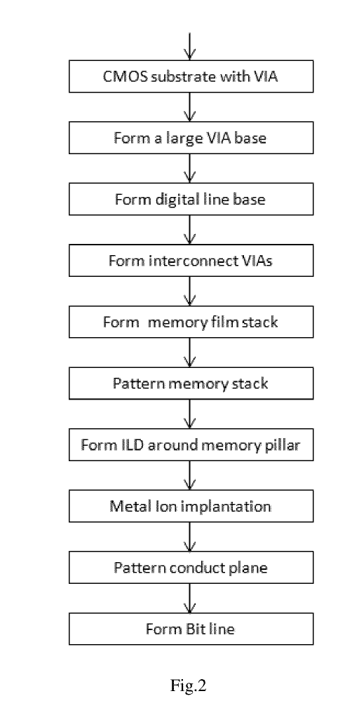

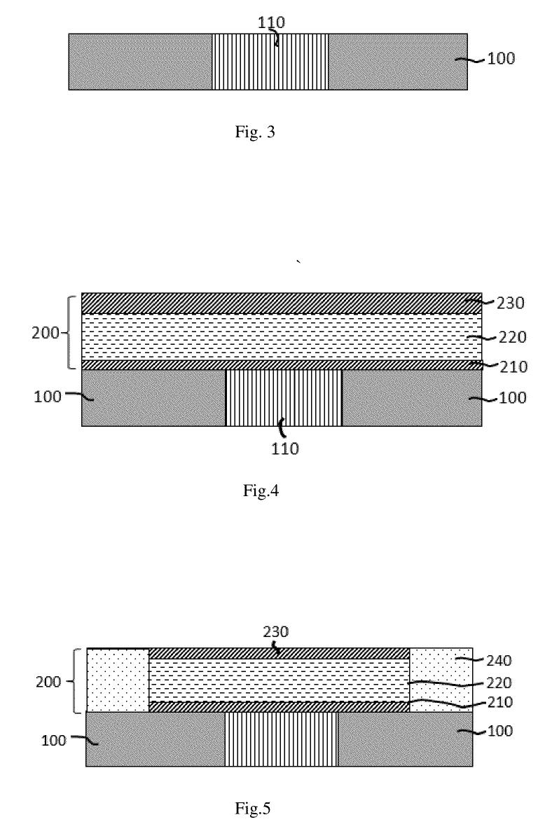

The fabrication process flow is shown in FIG. 2 which starts from a substrate [100 in FIG. 3] containing VIA (110) which is connected to the bottom CMOS control circuits already built (not shown). The process starts from the deposition of metallic multilayer with a typical film stack (200) of Ta (210)/Ru or Cu & Al alloy (220)/Ta (230) in FIG. 4, to form a large VIA base to accommodate the digital line in the middle. Typical thickness of these layers are 50 A Ta(210), 400 A Ru(220) and 200 A Ta(230).

By photolithography patterning, etch, dielectric refill (SiO2, 240) and CMP (FIG. 5) an isolated metal base is formed which connects to the VIA directly from the bottom. Such an isolated metal base can also be formed by oxygen ion implantation to convert the outer region into electrically insulated metal oxide.

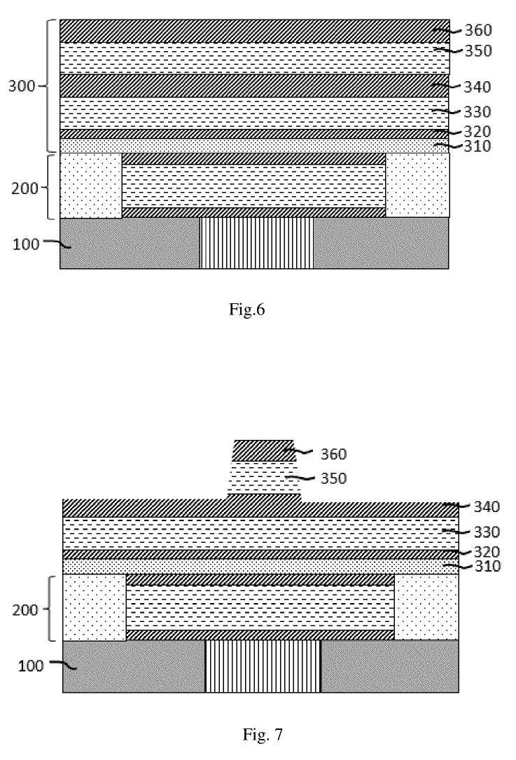

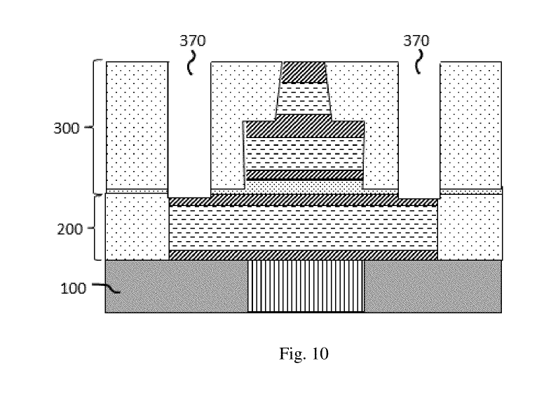

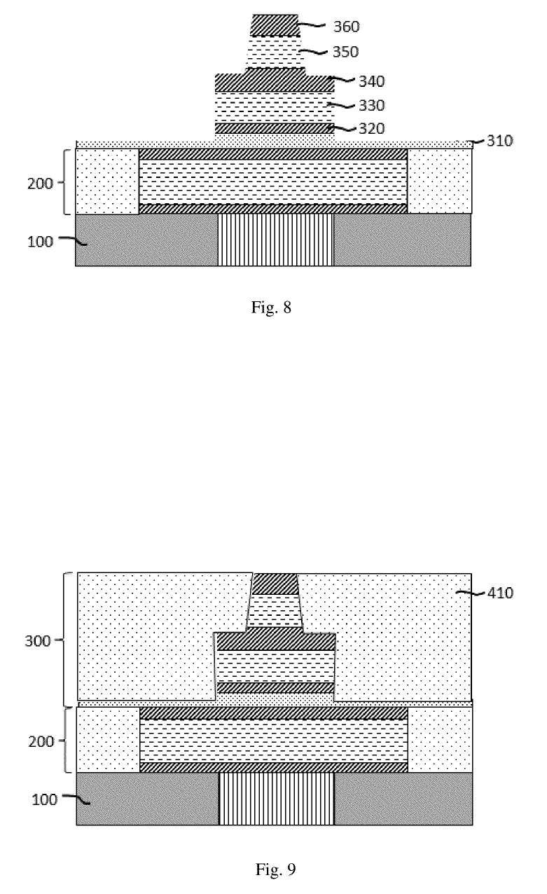

Then, a film stack (300) of ILD (310)/Ta(320)/metal(330)/Ta(340)/metal(350)/Ta(360) is deposited (FIG. 6) for digital line and a top pillar pointing towards the top memory cell. The bottom ILD (310) is needed to isolate the film stack 300 from the VIA metal base (200). The film thickness for each layer 100 A ILD(310), 50 A Ta(320), 400 A Ru or Cu&Al alloy (330), 200 A Ta(340), 400 A Ru or Cu&Al alloy(350), 200 A Ta(360). A top conducting pillar [FIG. 7] is formed by dual photolithography patterning and RIE to form a small Ta hard mask (360) using C,H,F containing chemical gas (such as CF4, CHF3), and then etch through the Ru layer (350) using CH3OH or CO & NH4 chemical gases, and stopped on the middle Ta layer (340) as described in our earlier patent application (see our own U.S. patent application Ser. No. 14/170,645). Then, another similar photolithography patterning and RIE (stopped in the middle of bottom insulating layer -310) to form a long stripe digital line with a smaller conducting pillar above (FIG. 8).

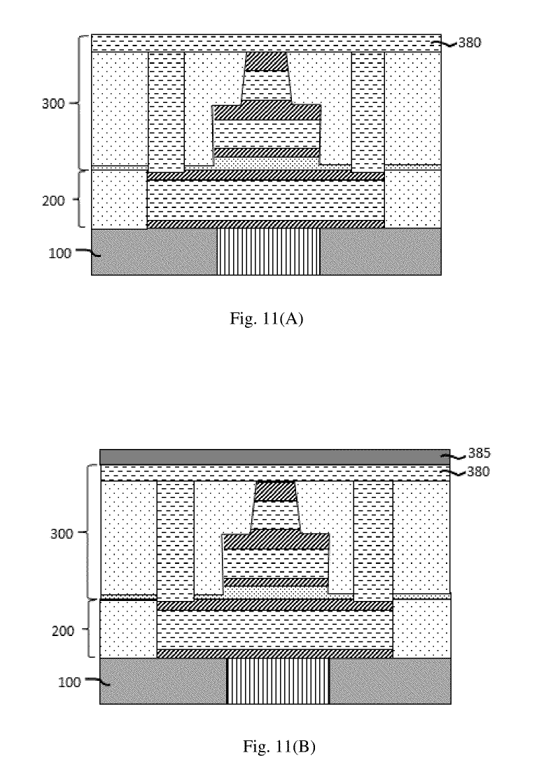

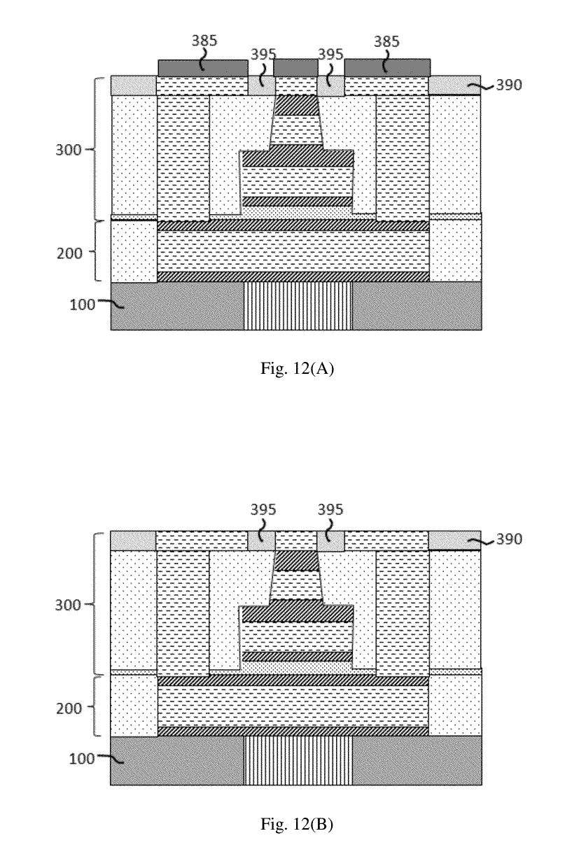

Then, a dielectric layer (SiO2, 410) is refilled in the etched area and flattened by CMP to cover the entire surface (FIG. 9). Then another photolithography patterning and etch are used to open a space down to the bottom VIA base (FIG. 10) and a metal (Cu & Al alloy or Ru) layer is grown conformally to form electric conductive paths between the bottom large VIA base and top memory layer (FIG. 11A) to be built. After a minor kis-lapping of the as-grown metal surface, an ion implantation hard mask layer (385) is deposited on top of metal layer (FIG. 11B). Typical ion mask material is either Ta or W with a thickness between 50-200 A. Then oxygen plasma ion implantation is used to convert the exposed metallic layer (380) into metal oxide insulating region (395) (see FIG. 12A). Then, a RIE is used to remove the remaining top ion mask layer to form a flat interface (FIG. 12B). The etchant gas could be C,H,F containing chemical gas (such as CF4, CHF3).

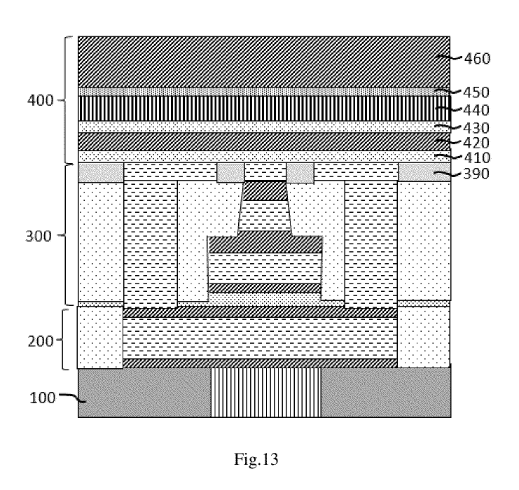

Then the memory cell film stack is deposited [FIG. 13], which contains an isolation layer (410)/memory layer (420)/MgO(430)/magnetic reference layer (440)/Ru cap (450)/top hard mask Ta(460). The ILD (410) is either a single MgO layer with a thickness of about 25 A, or bi-layer of 10AlOx/20MgO. The magnetic memory layer (420) contains either CoFeB or bi-layer of CoFeB/CoFe, MgO (430) is about 10 A, and the magnetic reference layer (440) has its magnetization aligned perpendicular to the plane. A typical material used for reference layer 440 is TbCo, CoPd, CoPt or their superlattice [Co/Pd]n, [Co/Pt]n. The Ru cap (450) has a thickness of 10-20 A is used to isolate the PM from the Ta hard mask (460) which has typical thickness of 100-400 A.

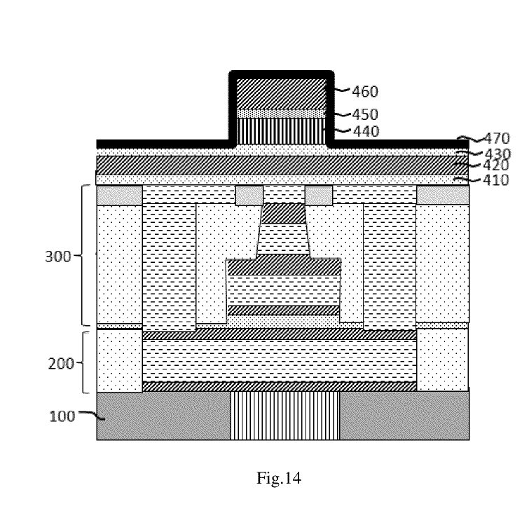

A dual photolithography patterning and etch (see our own U.S. patent application Ser. No. 14/170,645) is used to form a small Ta hard mask pillar (460) using C,H,F containing chemical gas (such as CF4) followed by oxygen ashing of the remaining photoresist and RIE redep. Then a chemical gas of CH3OH or CO/NH4 is used to etch the top Ru (450) cap and magnetic reference layer (440) and stops in the middle of MgO (430) using the just created Ta hard mask pillar. Immediately after etch, an insulating layer (ILD, 470) is deposited to conformally cover the exposed MgO junction edge and the entire flat surface [FIG. 14]. The ILD (470) can be either a single layer of 60AlOx, a bi-layer of 20MgO/50AlOx or 20SiN/50AlO. The AlOx or SiN can be formed by the ALD method.

Due to the presence of the ILD (410), the middle magnetic memory layer (420) is isolated from the top metal surface of VIA connecting to the bottom CMOS. In order to connect the middle memory layer to the underneath CMOS device, the ILD (410) outside the memory pillar must be conductive, which can be done by metal implantation to convert the isolated film stack (410-420,430) on the exposed surface outside the memory pillar into a thick conductive layer (480). Selection of metal for implantation can be Au, Ag, Cu, Ru, Li. After ion implantation, a high temperature anneal (>200 C) is needed to repair the film structure damage.

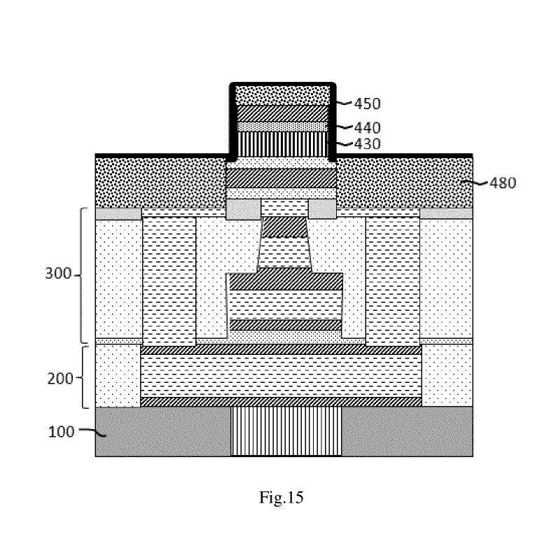

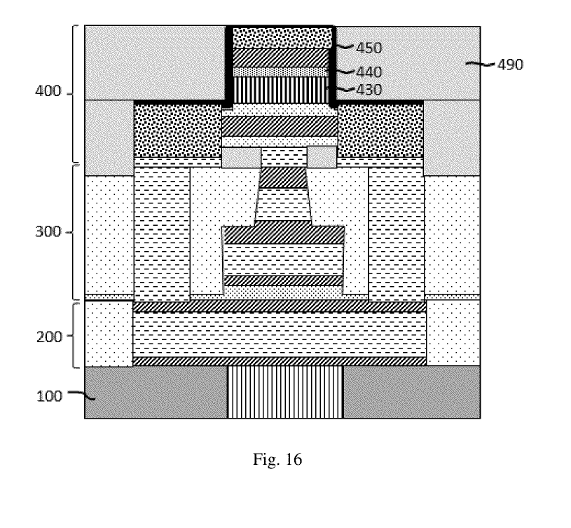

To create an isolated middle conductive base, a photolithography patterning is used to cover the middle memory area before removing the outside conductive surface by etching (FIG. 15). After etch, the surface is refilled with dielectric layer (SiO2, 490) and CMP to flatten the surface (FIG. 16).

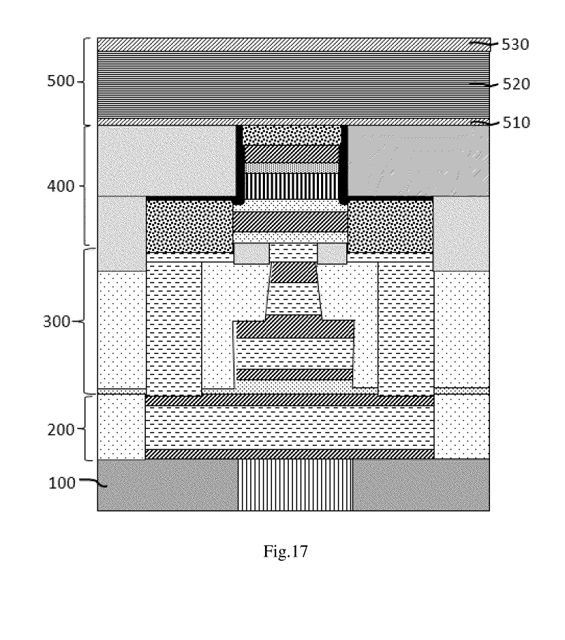

Finally, the top bit line is formed by deposition 50Ta (510)/500Ru(520)/100Ta(530), patterning, etch, dielectric (SiO2) refill and CMP, which has a magnetic memory cell sitting on a large VIA base in the middle and a digital line at the bottom with a metal pillar pointing towards the memory cell and a bit line on the top across each other (FIG. 17).

1. A magnetic random access memory has three terminals.

2. The element of claim 1, wherein the three terminals magnetic random access memory has a small foot print with its three terminals vertically overlaid and cross each other.

3. The element of claim 1, wherein the three terminals magnetic random access memory has its first electrode connected to the top magnetic reference layer, the second electrode connected to the middle memory layer, and the third electrode is underneath the bottom isolating layer pointing towards the middle memory cell.

4. The element of claim 1, wherein the three terminals magnetic random access memory contains a core film stack of bottom insulating layer (IL), a magnetic memory layer, a dielectric tunneling layer, a top magnetic reference layer.

5. The element of claim 3, wherein the top magnetic reference layer has its magnetization perpendicular to the plane and magnetization of the memory layer is modulated by the voltage between the first and third electrode, which could be perpendicular to the plane or lie in the plane.

6. The element of claim 3, wherein both the write and read currents flow through the said first and the second electrode.

7. The element of claim 5, wherein the write current can be reduced by applying a voltage between the first and third electrode.

8. The element of claim 3, wherein the three-terminal spin transistor memory has a large metal base on top of the VIA connecting to the CMOS control circuit, with film stack of Ta/Ru or Cu & Al alloy/Ta with a thickness of 20-50Ta/200-400 Ru/100-200Ta.

9. The element of claim 3, wherein the memory cell has an insulating layer one (ILD), magnetic memory layer, a MgO tunneling layer, a magnetic reference layer, a capping layer and a hard mask layer.

10. The element of claim 9, wherein the memory insulating layer one (ILD) is a single MgO with a thickness between 10-30 A, or a bi-layer of ALD/MgO with a thickness range of ALD: 10-20 A, MgO:10-20 A.

11. The element of claim 9, wherein the memory layer is CoFeB: 10-20 A or CoFeB/CoFe with CoFe as interface dusting layer (2-5 A).

12. The element of claim 9, wherein the top magnetic reference layer is CoTb, CoPt, CoPd with a thickness between 20-60 A, or superlattice [Co/Pd]/n, [Co/Pt]n.

13. The element of claim 9, wherein the top capping layer is Ru with a thickness between 10-20 A.

14. The element of claim 9, wherein the hard mask layer is Ta, or Ta alloy with a thickness between 100-400 A.

15. The element of claim 1, wherein the three terminals magnetic random access memory is formed by the formation of a large VIA base, formation of digital line pillar and stripe, formation of magnetic memory cell, formation of top bit line.

16. The element of claim 15, wherein the digital line has a film stack of Ta/X/Ta/X/Ta, or Ta/NiFe/X/NiFe/Ta/X/Ta with X being Ru, Cu, Al, Au, or alloy of them, with bottom Ta thickness between 10-30 A, middle Ta between 100-400 A and top Ta thickness between 100-400 A, X thickness is between 100-500 A and NiFe thickness between 20-60 A.

17. The element of claim 15, wherein digital line is isolated from the bottom VIA base by a dielectric layer insulating layer such as Al2O3, SiO2, Si3N4 with a thickness between 50-200 A.

18. The element of claim 15, wherein the large VIA base is formed by film stack deposition, photolithograph patterning, metal etch, dielectric refill and CMP.

19. The element of claim 15, wherein the VIA base film stack is Ta/Ru or Cu & Al alloy/Ta and photolithography patterned and etched with CF4 for top Ta hard mask, CH3OH or CO & NH4 for the middle Ru or Cu & Al and bottom thin Ta.

20. The element of claim 15, wherein the etched VIA base is refilled with SiO2 and CMP to flatten the surface.

21. The element of claim 15, wherein the VIA base can also be formed by oxygen ion implantation to convert the exposed area into electrically insulating dielectric region.

22. The element of claim 16, wherein the digital line is dual photolithography patterned and etched to form Ta small pillar hard mask using C,H,F containing chemical gas, such as CF4, CF3H.

23. The element of claim 16, wherein the digital line Ta pillar is used as a hard mask and another etch using CH3OH or CO & NH4 is used to etch the underneath Ru and stops on the middle Ta.

24. The element of claim 22, wherein another photolithography pattern is used to define the long stripe digital line and CF4 is used to remove middle Ta layer, then photoresist is removed and CH3OH or CO & NH4 is used to remove the second Ru layer and the bottom thin Ta.

25. The element of claim 22, wherein said the etched digital line is refilled with SiO2 and CMP to flatten the surface.

26. The element of claim 22, wherein another photolithography patterning is used to create a surrounding vertical open space for the large VIA to connect to the top memory cell.

27. The element of claim 26, wherein a metal layer, Ru or Cu is formed in the open grove by electric plating or atomic layer deposition to connect the large VIA base to the top memory layer to be built.

28. The element of claim 27, wherein an ion implantation mask layer, Ta or W is deposited on top of the metal layer, with a film thickness between 50 A to 200 A.

29. The element of claim 22, wherein another photolithography pattern and RIE etch are used to create ion implantation mask, and CF4 gas is used to remove the exposed Ta or W material.

30. The element of claim 29, wherein oxygen ion implantation is used add oxygen ions into the exposed metal layer to form electrically isolated metal oxide region.

31. The element of claim 30, wherein oxygen ion implantation can be either oxygen plasma immersion ion implantation in a normal RIE or IBE process chamber or regular ion implanter.

32. The element of claim 31, wherein another RIE etch are used to remove the remaining ion implantation mask material Ta or W using CF4 or other C,F,H containing etchant gas.

33. The element of claim 32, wherein the memory film stack containing ILD/memory layer/MgO/reference layer/Ru/Ta is deposited.

34. The element of claim 33, wherein the hard mask Ta is etched using chemical gas CxFyHz, such as CF4, CF3H, and stop on Ru cap, and the remaining photoresist and associated Ta redep is removed by O2 or Ar/O2.

35. The element of claim 33, wherein the remaining layers are etched using chemical gases CO & NH4 or CH3OH, C2H5OH, and stops on MgO controlled by end point control.

36. The element of claim 35, wherein the etched memory and MgO junction is conformally covered by a thin of dielectric layer, such as AlOx by atomic layer deposition (ALD), or bi-layer of MgO/ALD, SiN/ALD with a film thickness of 40-80 A ALD, 20MgO/40-60ALD, 20SiN/40-60ALD.

37. The element of claim 36, wherein the ALD on the flat surface is removed by low angle (perpendicular) ion mill, and the ALD on the vertical edge surrounding MgO junction is still present after perpendicular ion mill.

38. The element of claim 37, wherein ion implantation by metal, Li, Cu, Au, Ru, Pt into the buried ILD region to convert it into an electrically conductive layer.

39. The element of claim 29, wherein another photolithography pattern and etch is used to define an isolate memory cell by removing the conductive layer (formed by ion implantation from the rest of the open area).

40. The element of claim 3, wherein the three terminals magnetic random access memory has a bit line formed on top of memory cell by film deposition Ta/X/Ta or Ta/NiFe/X/NiFe/Ta with X is Ru, Cu, Al, Au, or alloy of them, with bottom Ta thickness between 10-30 A, middle Ta between 100-400 A and top Ta thickness between 100-400 A, X thickness is between 100-500 A and NiFe thickness between 20-60 A.

41. The element of claim 40, wherein the bit line is formed by patterning and etching to form Ta hard mask using C,H,F containing chemical gas, such as CF4, CF3H and second etch using CH3OH or CO & NH4 to completely etch the remaining film stack.

42. The element of claim 41, wherein the etched bit line is filled with SiO2 and CMPed to flatten the surface.

43. The element of claim 3, wherein the said three terminals magnetic random access memory is finally annealed to repair the damaged film structure by ion implantation with an annealing temperature no less than 200 C and an annealing time no less than half hour.
